(19) United States
(12) Patent Application Publication
(10) Pub. No.: US 2009/0013527 A1
(43) Pub. Date: Jan. 15, 2009

(54) COLLAPSABLE CONNECTION MOLD REPAIR METHOD UTILIZING FEMTOSECOND LASER PULSE LENGTHS

(75) Inventors: Timothy E. Neary, Essex Junction, VT (US); Erik M. Probstfield, Essex Junction, VT (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/775,918

(22) Filed: Jul. 11, 2007

(51) Int. Cl. H05K 3/02; H01R 12/14

(52) U.S. Cl. 29/852; 174/255; 219/121.68; 219/121.73; 361/777

(57) ABSTRACT

A method for repairing molds for collapsible connections utilizing a femtosecond laser pulse length. Also provided is a laser source for implementing a multistep profile repair process for the removal of excess material in C4 molds by utilizing the femtosecond laser pulse lengths.

### BACKGROUND OF THE INVENTION

1. Field of the Invention

The present invention relates to the provision of a method for repairing molds for collapsible connections utilizing a femtosecond laser pulse length. In essence, the invention is also directed to the provision of a multistep profile repair process for the removal of excess material in C4 molds by utilizing the femtosecond laser pulse lengths.

Presently in the technology, there is being developed new processes for introducing metallurgical connections (C4s) to 300 mm semiconductor wafers. Various lots of wafers, which are processed through wafer inspection stations, have evidenced the presence of a significant problem with either missing or reduced size C4 connections. The defects present themselves by showing up during inspection with so-called capture pads that are encountered with missing C4s, or as small undersized C4s on the printed capture pads. This type of defect is a detriment to obtaining a satisfactory reliability and causes a reduced output yield, and necessitates corrective measures to be taken in order to allow meeting customer commitments and requirements. The method for delivery of the material to form the C4 is new and relies on a mold with semi-spheres etched chemically or physically into the mold surface as a capture/holding space for the metallurgy that will later be transferred to the capture pad on the wafer surface. The mold material currently being employed comprises boron-doped quartz, which facilitates isotropic etching, and which results in the semi-spherically-shaped geometry. At this time, the technology lacks a viable repair process that would allow for or facilitate the correction of the mold because semi-spheres so as to eliminate random defects encountered in the mold build-up processes.

A mold is employed in a new collapsible connection interface method utilizing metallurgical bumps or C4s, wherein the mold contains a specific volume of material prior to transferring the material to a semiconductor device being produced or semiconductor die. In case a depression in the mold is missing for a single C4, considered to be excess material, the mold is deemed to be in need of repair since all of the C4 depressions are required for material containment. Thus, if the mold has a missing depression at any given location, the transfer of C4 material will not occur as is desired. If one C4 on the device is missing due to a mold defect, the device will be rejected because it lacks a C4, which represents an issue as to a reliability and output yield. At this time, no repair methodology is in use in industry or in the technology.

2. Prior Art

Pursuant to the current state of the prior art, none of the publications known in this technology disclose the present inventive concept.

Kamada, et al., U.S. Pat. No. 7,007,512 B2, disclose a method for machining glass substrates, wherein a surface of a glass substrate is irradiated with a laser beam to form V-shaped groups. Although this patent relates to the treatment of substrate surfaces through the intermediary of laser beams, there is no process or method disclosed for repairing collapsible molds utilizing femtosecond laser pulse lengths as described by the present invention.

Cummings, et al., U.S. Pat. No. 6,864,460 B2 disclose a method of ablating an opening in a hard, non-metallic substrate, whereby a laser beam forms holes of various sizes and shapes in a glass surface through the intermediary of pulsed laser processing wherein successive layers of the substrate may be ablated to generate a hole therein. Again, although this relates to the treatment of surfaces of substrates in order to form predetermined indentations for holes therein, there is no disclosure of a method for repairing molds for collapsible connections utilizing femtosecond laser pulse lengths in accordance with the inventive concept.

Kresge, U.S. Pat. No. 6,483,074 B2 discloses laser beam systems for processing micro via formations in a substrate; however, there does not relate to methods for collapsible connect mold repairs utilizing femtosecond laser pulse lengths in order to compensate for undersized or lacking molded connects, such as C4s connections.

Finally, Ngoi, et al., U.S. Pat. No. 6,285,002 B1 disclose three-dimensional micro machining through the use of ultra short modulated laser pulses for treating the surface of a substrate by means of femtosecond pulsing; however, this patent does not disclose the repair of collapsible connection molds utilizing femtosecond laser pulse lengths analogous to the inventive concept as described and claimed herein.

### SUMMARY OF THE INVENTION

Pursuant to the invention, a repair of missing or reduced semi-spherical holes is implemented by utilizing a femtosecond pulse length laser in order to ablate the surface of the mold. The use of the short pulse laser is critical to the successful implementation of this repair for several reasons. Hereby, the nature of laser ablation requires absorption of light energy with a short pulse laser, <200 fs, so that energy is delivered at such a rate that the material is vaporized prior to thermal melting and eruption due to boiling. Moreover, the doped nature of the utilized quartz adds to the absorption characteristic of the material and facilitates the workability of the ablation process.

Another benefit of a femtosecond short pulse laser is that molten slag at the boundary of the laser image is prevented from piling up. This effect is called roll up and is avoided by use of the femtosecond laser. With a 10-20μ-ablation removal rate, based on the doping concentration in the quartz, the number of pulses required is calculated to obtain the required depth. This removal and the aperture size for the laser can be used to calculate the desired aggregate volume removal to match the

Basically, the present invention utilizes a scan of the mold to determine the presence of the mold features, i.e., depressions of a given or specified volume. In case a feature is missing, and therefore signifies the presence of has excess material, the scan process then recognizes the location of the missing feature and defines the location that requires implementing a repair. The unique attribute of the invention resides in the use of a short pulse layer, such as, for example, <150 femtoseconds in duration, in order to ablate a stair step-shaped depression in the mold that can be precisely controlled to thereby define the desired volume of material for future transfer thereof to the semiconductor device. The stair step-shape allows for a sequential ablation of enlarging diameter circles or polygons, as may be defined by the employed laser aperture. Thus, a first ablation step will have a defined depth, which is based on ablation rates, and the volume can be calculated based on geometry. A second ablation step will have a similar depth but with a larger diameter, and wherein the depth of the second ablation will extend across the entire aperture field such that the stepped feature will be replicated into the mold. Additional ablation steps and with increased diameters can be employed until there is defined the desired volume in the mold. This process can be repeated for any number of defects on the mold at locations where no depression are present.

Another feature of the present invention resides in the ability thereof to modify the volume of a depression with the application of a single ablation of the femtosecond laser. Once a small essentially undersized C4 is discovered, the mold can be repaired to increase the volume to an acceptable level.

Accordingly, it is an object of the present invention to provide a method for repairing molds for collapsible connections utilizing a femtosecond laser pulse length.

A further object of the invention resides in the provision of a multi-step profile repair process for the removal of excess material in C4 molds by utilizing the femtosecond laser pulse length.

Still another object of the present invention resides in the modification of a volume of a depression through a single ablation of a femtosecond laser in order to increase the volume of an undersized C4 connection to an acceptable level.

### BRIEF DESCRIPTION OF THE ACCOMPANYING DRAWINGS

Reference may now be made to the following detailed description of preferred embodiments of the invention, taken in conjunction with the accompanying drawings; in which:

FIGS. 11A and 1B illustrate, respectively, top plan and cross-sectional diagrammatic views of a portion of a mold illustrating semi-spherical depressions and a defective depression requiring a repair utilizing a femtosecond laser pulse pursuant to the invention;

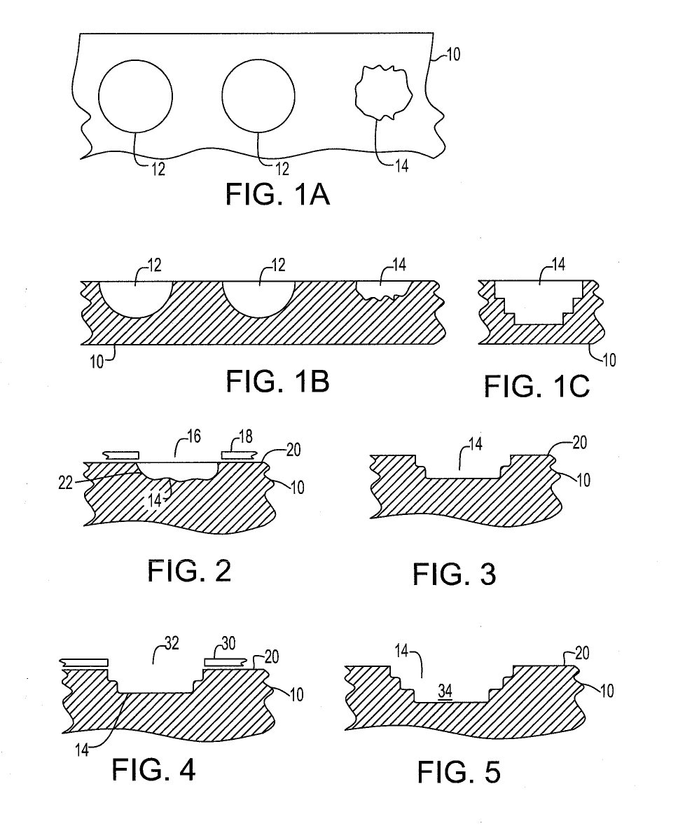

FIG. 1C illustrates a fragmentary sectional view of the mold diagrammatically showing the repaired defective depression as a result of a laser ablation;

FIGS. 2 through 5 illustrate, respectively, sequential steps employed in the repair process of defective mold recesses with the application of femtosecond laser pulse lengths pursuant to the invention;

FIG. 6 illustrates a further cross-sectional view through a mold portion of defining a photoresist process in the treatment of the defect in the mold recess;

FIG. 7 reflects a reflow process in the treatment of the recesses of FIG. 6;

FIG. 8 illustrates a treatment of the defective recess showing the site of a localized ablation with the femtosecond laser pulse length; and

FIG. 9 illustrates the repaired mold location of FIG. 8 utilizing the femto laser pulse length pursuant to the present invention.

### DETAILED DESCRIPTION OF THE INVENTION

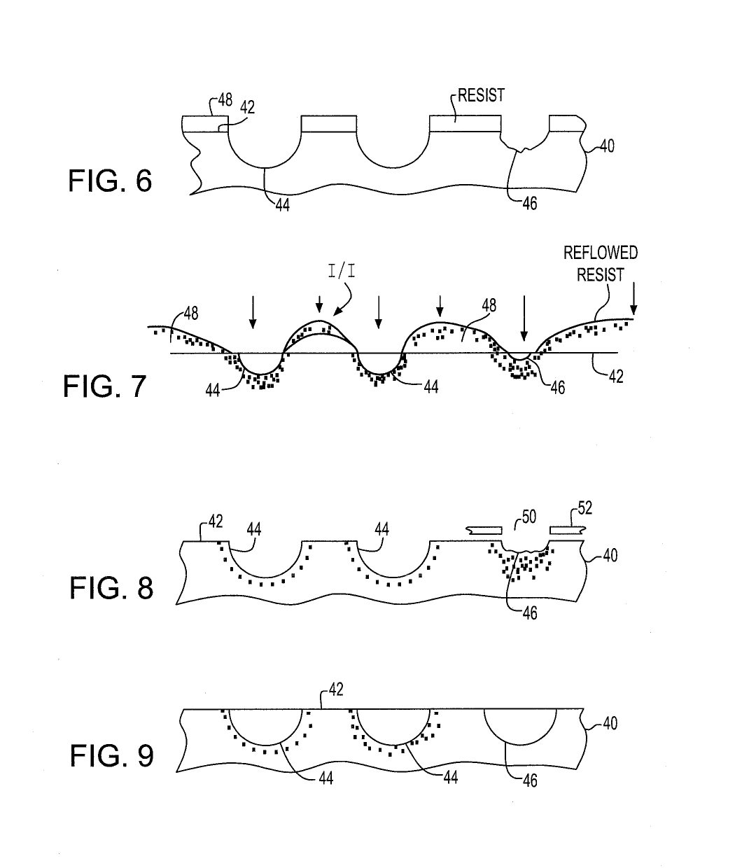

Referring in detail to the drawings, and particularly FIGS. 1A and 1B, there is diagrammatically illustrated a segment of a semiconductor mold 10, which may be comprised of a quartz material, incorporating recesses 12 which possess the necessary semi-spherical configurations for the forming of the C4 connections during the manufacturing processing thereof. As shown, one of the recesses 14 has a defective configuration deviating from those of recesses 12, being either irregular in cross-sectional view, as shown in FIG. 11A, significantly shallower in depth, as shown in FIG. 1B, so as to result in the formation of C4s which are either undersized or irregular in shape or both.

In order to impart a necessary corrective repair action to the defective recess 14, as shown in the sequential steps of FIGS. 1C-5 of the drawings, and particularly referring to FIG. 1C, this illustrates the defective depression or recess 14 having been treated in a stepped or staircase-shaped laser ablation process pursuant to the invention, utilizing femtosecond laser pulse lengths, as described herein.

As illustrated in the process of repair step of FIG. 2, an aperture 16 is defined in a laser mask 18, which is superimposed on the mold surface 20, with the aperture 16 being located above and in alignment with the defective recess 14 in the mold surface 20 of the mold 10. A smaller perimeter 22 is computationally defined, and ablation of the recess 14 is thereby effected by means of a femtosecond laser pulse length to ablate approximately 10-25% of the total volume of the recess 14 in the first repair step, as shown diagrammatically in FIG. 3.

As represented diagrammatically in FIG. 3 of the drawings, the perimeter of the recess 14 has been expanded and the ablation by means of the femtosecond laser pulse is continued to provide stair step-shaped one or more further and deeper recess configurations, as described hereinbelow.

The stepwise repair process is then continued by again superimposing a mask 30 with a larger aperture 32 above the previously ablated recess 14, as represented in FIG. 4, and ablation with the femtosecond laser process is repeated until volume is achieved and until, as shown in FIG. 5, the stepped repair recess possesses a volume 34, which is similar to that of the correct semi-spherical recess or depressions 12 in the mold 10. This process is repeated any number of times until the desired recess volume is attained by means of the stair step-shaped ablation process utilizing the femtosecond laser pulse lengths, as described hereinabove, i.e., such as, for example, <200 fs, or even <150 fs.

Pursuant to a modification of the invention, as illustrated in FIG. 6 of the drawings, in that instance, the mold 40 has surface semi-spherical recesses 44 and also contains a recess 46, which is somewhat shallow and may possess incorrect or irregular dimensions, as also shown in FIG. 1B of the drawings. A photoresist layer 48 is applied to the surface 42 of the mold 40. A photoresist process is employed using an original masking method for mold build-up, as is well known in the technology.

Reflow of the resist to define the slope and internal dimension is provided, as shown in FIG. 7, so that this essentially covers the various recesses in the mold. At this time, a blanket I/I process is used to define a profile in the mold so as to enhance the femtosecond ablation. The resist profile allows for a tapered I/I in the mold to control the slope of the final ablation. The femtosecond laser ablation process is imparted thereto as represented in FIGS. 3-5 in order to determine the appropriate size and configuration, as indicated in FIG. 8 of the drawings. In that instance, the aperture 50 of a mask 52 for laser ablation is superimposed on the defective recess (or recesses) 46, and localized stepwise ablation by means of the femtosecond laser pulses is applied at the selected local site. This ablation process is repeated until, as shown in FIG. 9, the initially defective recess 46 assumes a shape, which possesses the required size and depth in conformance with the remaining acceptable semi-spherical recesses and forms a repaired mold location meeting the requirements for implementation of a satisfactory manufacturing process in forming the C4 connections.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but to fall within the spirit and scope of the appended claims.

What is claimed is:

1. A method of repairing at least one recess in semiconductor mold substrate surfaces, wherein said at least one recess is provided for the formation of collapsible connections, said recess being initially of an undersized or irregular defective configuration, deviating from a desired configuration, said method comprising:
superimposing a pulsed laser source having an aperture in alignment over said at least one defective recess in said mold substrate surface; and
applying femtosecond laser pulses to said at least one recess so as to remove material therefrom so as to impart said desired configuration to said at least one recess.

2. A method as claimed in claim 1, wherein said femtosecond laser pulses are applied in sequential steps so as to enlarge said at least one defective recess in a stair step-shaped configuration.

3. A method as claimed in claim 2, wherein said femtosecond laser pulses are applied through the application of successively larger apertures over said at least one defective recess.

4. A method as claimed in claim 2, wherein said mold substrate surfaces include recesses of substantially semi-spherical configuration for producing C4 connections.

5. A method as claimed in claim 2, wherein said at least one defective recess is enlarged by said femtosecond laser pulses to attain a volume approximately that of one of said semi-spherical recesses.

6. A method as claimed in claim 5, wherein said volume of said at least one repaired defective recesses is attained by applying a plurality of separate and sequential femtosecond laser pulse lengths to said at least one defective recess.

7. A method as claimed in claim 1, wherein said at least one defective recess and desired semi-spherical recesses in the mold substrate surfaces are detected by an inspection of said surfaces prior to being positioned in a laser ablation operative locale upon detection of said at least one defective recess.

8. A method as claimed in claim 7, wherein said recesses are formed in said mold substrate surfaces through the imposition of a photoresist masking process for mold build-up.

9. A method as claimed in claim 8, wherein an I/I process provides for a reflow of said resist so as to create a tapered I/I in the mold to control the slope of the final ablation.

10. A method as claimed in claim 1, wherein said femtosecond laser pulse lengths are shorter than about 150 to 200 femtoseconds.

11. An ablating pulse laser for repairing at least one recess in semiconductor mold substrate surfaces, wherein said at least one recess is provided for the formation of collapsible connections, said recess being initially of an undersized or irregular defective configuration, deviating from a desired configuration, comprising:
superimposing a pulsed laser source having an aperture in alignment over said at least one defective recess in said mold substrate surface; and
applying femtosecond laser pulses to said at least one recess so as to remove material therefrom so as to impart said desired configuration to said at least one recess.

12. A laser as claimed in claim 11, wherein said femtosecond laser pulses are applied in sequential steps so as to enlarge said at least one defective recess in a stair step-shaped configuration.

13. A laser as claimed in claim 12, wherein said femtosecond laser pulses are applied through the application of successively larger apertures over said at least one defective recess.

14. A laser as claimed in claim 12, wherein said mold substrate surfaces include recesses of substantially semi-spherical configuration for producing C4 connections.

15. A laser as claimed in claim 12, wherein said at least one defective recess is enlarged by said femtosecond laser pulses to attain a volume approximately that of one of said semi-spherical recesses.

16. A laser as claimed in claim 15, wherein said volume of said at least one repaired defective recesses is attained by applying a plurality of separate and sequential femtosecond laser pulse lengths to said at least one defective recess.

17. A laser as claimed in claim 11, wherein said at least one defective recess and desired semi-spherical recesses in the mold substrate surfaces are detected by an inspection of said surfaces prior to being positioned in a laser ablation operative locale upon detection of said at least one defective recess.

18. A laser as claimed in claim 17, wherein said recesses are formed in said mold substrate surfaces through the imposition of a photoresist masking process for mold build-up.

19. A laser as claimed in claim 18, wherein an I/I process provides for a reflow of said resist creating a tapered I/I in the mold for controlling the slope of the final ablation.

20. A laser as claimed in claim 11, wherein said femtosecond laser pulse lengths are shorter than about 150 to 200 femtoseconds.
